(19) United States
(12) Patent Application Publication
(10) Pub. No.: US 2011/0174612 A1
(43) Pub. Date: Jul. 21, 2011

(54) SPUTTERING APPARATUS WITH ROTATABLE SPUTTERING TARGET

(75) Inventor: CHIA-YING WU, Tu-Cheng (TW)

(73) Assignee: HON HAI PRECISION INDUSTRY CO., LTD., Tu-Cheng (TW)

(21) Appl. No.: 12/774,699

(22) Filed: May 5, 2010

(30) Foreign Application Priority Data
Jan. 19, 2010 (CN) 201010300418.6

(51) Int. Cl. C23C 14/34

(52) U.S. Cl. 204/298.23

(57) ABSTRACT

A sputtering apparatus includes a chamber including a first sidewall and defining a number of evenly spaced first through holes on the first sidewall, a number of slide rails radially extending outwards from the first sidewall corresponding to each first through hole, a number of target holders defining at least two sputtering faces and slidably engaged with the slide rails, and a target material mounting on the sputtering faces. The target holder includes a shaft; the sputtering face capable of rotating about the shaft. The target holders are fastened to the first sidewall with one of the sputtering faces facing the first through hole, the sputtering face capable of being replaced by rotating about the shaft.

### BACKGROUND

1. Technical Field

The present disclosure relates generally to the field of sputtering technology, and more particularly, to a sputtering apparatus with rotatable sputtering target capable of replacing a target material easily and rapidly.

2. Description of Related Art

Sputtering is a physical vapor deposition (PVD) process whereby atoms in a solid target material are ejected into the gas phase due to bombardment of the material by energetic ions. With advantages such as good deposition efficiency, precise deposition control and relative low cost, sputtering has become a popular deposition process in industry.

Generally, a typical sputtering apparatus includes a chamber, a target holder, and a target material. The target material is positioned on the target holder. The target holder is fastened in the chamber. When the target material on the target holder is required to be changed, the target holder is typically detached from the chamber before a new target material is reloaded. This is inconvenient and time-consuming.

Therefore, it is desirable to provide a sputtering apparatus which can overcome the above-mentioned problems.

### BRIEF DESCRIPTION OF THE FIGURE

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic, perspective top view of a sputtering apparatus according to one embodiment, the sputtering apparatus including a chamber and a target holder.

FIG. 2 is a schematic, enlarged front view of the target holder of the sputtering apparatus of FIG. 1.

FIG. 3 is a partial, perspective side view of the sputtering apparatus of FIG. 1, showing the target holder slid away from the chamber.

FIG. 4 is a partial, perspective side view of the sputtering apparatus of FIG. 1, showing the target holder fastened to the chamber.

### DETAILED DESCRIPTION

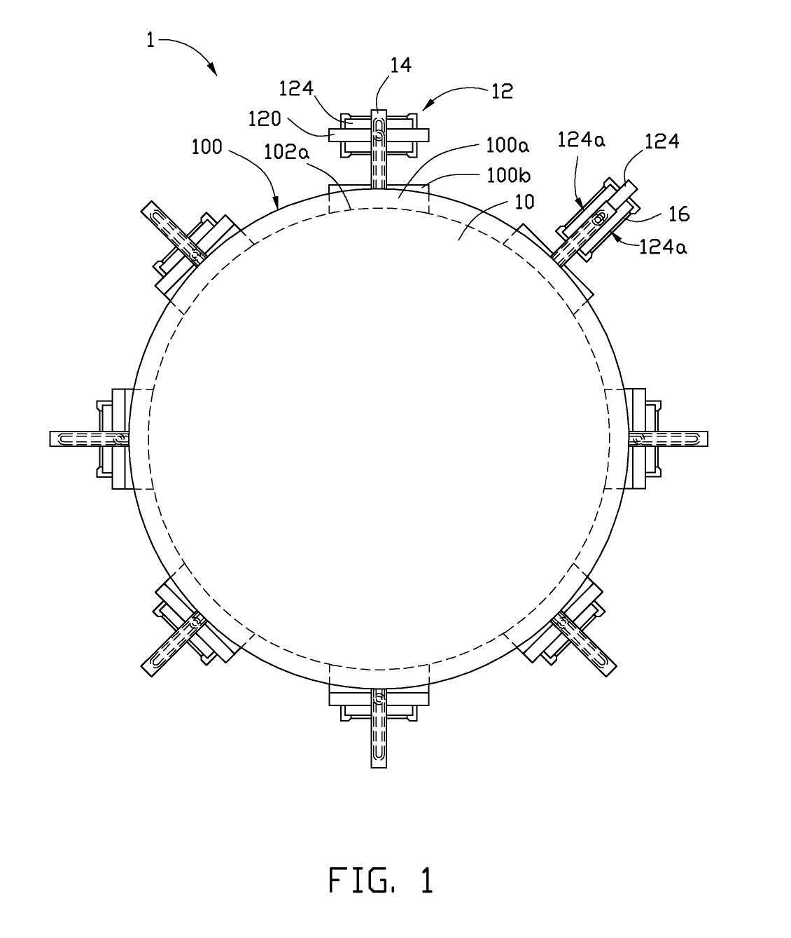

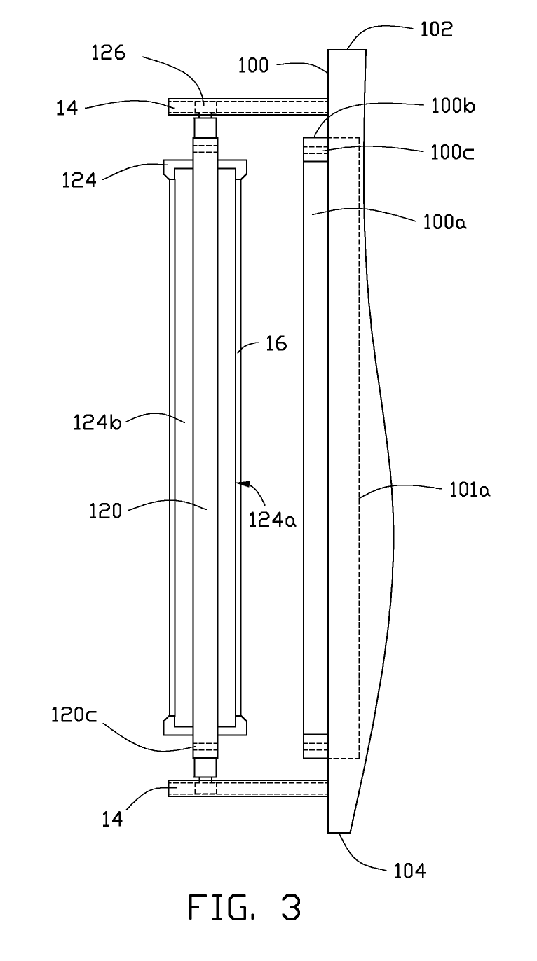

Referring to FIGS. 1 and 3, a sputtering apparatus 1 in accordance with one embodiment of the present disclosure is shown. The sputtering apparatus 1 includes a chamber 10, a number of target holders 12, a number of slide rails 14, and a number of sputtering targets 16.

The chamber 10 is substantially cylindrical and includes an upper cover 102, a bottom cover 104, a cylindrical first sidewall 100, and a number of connecting frames 100b. The upper cover 102 and the bottom cover 104 perpendicularly connect two opposite sides of the first sidewall 100, respectively. The chamber 10 defines a number of first through holes 100a radially arranged in the first sidewall 100 at predetermined intervals. Each first through hole 100a is substantially rectangular and defines a pair of long sides 101a and a pair of short sides 102a. The long sides are substantially parallel to a central axis of the chamber 10. Each connecting frame 100b perpendicularly protrudes from the first sidewall 100 to surround the entrance of each first through hole 100a. The chamber 10 defines a number of threaded holes 100c in each connecting frame 100b.

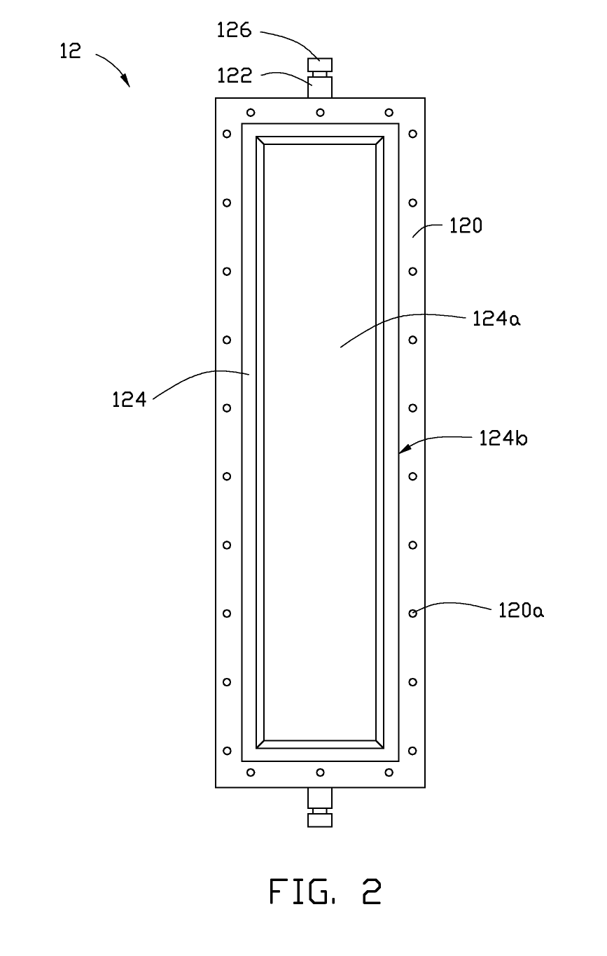

Also referring to FIG. 2, each target holder 12 includes a base 124, a flange 120, a shaft 122, and a pair of sliding blocks 126. In this embodiment, the base 124 is substantially rectangular prism-shaped and includes a pair of parallel sputtering faces 124a and a second sidewall 124b. The sputtering faces 124a are perpendicularly connected to the second sidewall 124b. The sputtering face 124a is similar to the first through hole 100a in shape and size. Alternatively, the number of the sputtering faces 124a can be more than two. For example, the base 124 can be triangular, rectangular, or pentagonal etc. Each sidewall of the prism can be a sputtering face.

The flange 120 perpendicularly extends outwards and frames the second sidewall 124b. The target holder 12 defines a number of second through holes 120a in the flange 120 spatially corresponding to the threaded holes 100c. The shaft 122 passes through the base 124 and the flange 120 and aligns with a longitudinal central axis of the base 124. The sliding blocks 126 are correspondingly formed at two opposite ends of the shaft 122.

The target materials 16 correspondingly are mounted on each sputtering face 124a. In alternative embodiments, two kinds of target materials 16 are mounted on the opposite sputtering faces 124a, respectively.

The slide rails 14 are radially provided on the first sidewall 100. The slide rails 14 are substantially pole-shaped. Each pair of the slide rails 14 are perpendicularly connected to the first sidewall 100 at opposite sides of the first through hole. One of the pair of slide rails 14 is positioned between the upper cover 102 and short sides 102a, the other of the pair of slide rails 14 is positioned between the bottom cover 104 and the other short side 102a.

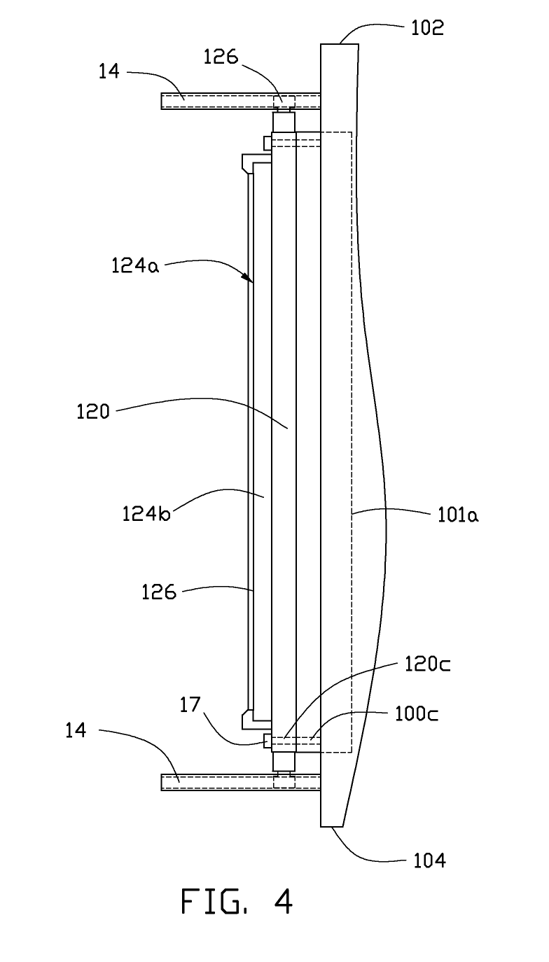

Also referring to FIGS. 3 and 4, in assembly, the sliding blocks 126 are slidably engaged with the slide rails 14 for making the target holder 12 slide back and forth along the slide rails 14. Each base 124 can rotate around the shaft 122 to select one of the sputtering faces 124a to face the first through hole 100a. The second through holes 120a correspondingly align with the threaded holes 100c. The target holder 12 is fastened to the first sidewall 100 by correspondingly threading a number of bolts 17 into the threaded holes 100c via the second through holes 120a. Thus, one of the sputtering faces 124a is selected to be sealed in the chamber 10 and the other sputtering face 124a is exposed outside the chamber 10.

When the target material 16 on the sealed sputtering face 124a runs out, the bolts 17 are unscrewed to release the target holder 12 from the first sidewall 100. The target holder 12 slides away from the first sidewall 100. The base 124 rotates around the shaft 122 to make the unused sputtering face 124a mounted on the target material 16 face the first through hole 100a. The target holder 12 slides back to the first sidewall 100. The target holder 12 is fastened to the first sidewall 100 to seal the unused sputtering face 124a in the chamber 10. The target material 16 can be reloaded onto the exposed sputtering face 124a while sputtering is in process. Thus, the sputtering face 124a can be easily replaced and the time for reloading the target material 16 can be saved.

While various exemplary and preferred embodiments have been described, it is to be understood that the invention is not limited thereto. To the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A sputtering apparatus comprising:
a chamber comprising a first sidewall and a first through hole defined in the first sidewall;
a target holder comprising a base, the base comprising at least two sputtering faces;
two parallel slide rails extending outwards from the first sidewall; and
a sputtering target mounted on each sputtering face, the base having opposite ends coupled to the slide rails, the opposite ends being rotatable about an axis perpendicular to the slide rails so as to enable the sputtering target on either one of the sputtering faces to be oriented to face the first through hole, the opposite ends being slidable along the slide rails so as to enable either one of the sputtering faces to engage in and close the first through hole.

2. The sputtering apparatus as claimed in claim 1, wherein the chamber is substantially cylindrical and further comprises an upper cover, a bottom cover, and a connecting frame, the upper cover and the bottom cover perpendicularly connect two corresponding opposite sides of the first sidewall, the connecting frame perpendicularly extends outwards from the first sidewall to surround the entrance of the first through hole.

3. The sputtering apparatus as claimed in claim 2, wherein the first through hole is substantially elongated rectangular, and comprises a pair of first sides and a pair of second sides, the first sides of the first through holes are parallel to a central axis of the chamber.

4. The sputtering apparatus as claimed in claim 2, wherein the base is substantially rectangular prism and further comprises a second sidewall perpendicularly connecting the sputtering faces and a shaft passing through the base and aligning with a central axis of the base, two opposite ends of the shaft are slidably and rotatably engaged with the slide rails.

5. The sputtering apparatus as claimed in claim 4, wherein the target holder further comprises a flange surrounding the periphery of the second sidewall, the chamber defines a number of threaded holes in the connecting frame, the target holder defines a number of second through holes in the flange spatially corresponding to the threaded holes, the target holder is fastened to the first sidewall by threading a number of bolts into the threaded holes via the second through holes.

6. The sputtering apparatus as claimed in claim 1, wherein each target holder further comprises a pair of sliding blocks correspondingly formed at the opposite ends thereof, the target holder is slidably engaged with the slide rails through the sliding blocks.

7. A sputtering apparatus comprising:
a chamber comprising a first circumferential sidewall and a number of equidistantly spaced first through holes radially defined in the first sidewall;
a number of target holders spatially corresponding to the first through holes, each target holder comprising at least two sputtering faces;
a number pairs of slide rails radially extending outwards from the first sidewall spatially corresponding to the first through holes, each pair of slide rails perpendicularly extending from the first sidewall at opposite sides of the first through hole; and
a number of sputtering targets respectively mounted on the sputtering faces, each target holder having opposite ends coupled to the respective pair of the slide rails, the opposite ends thereof being rotatable about an axis perpendicular to the slide rails so as to enable the sputtering target on either one of the sputtering faces to be oriented to face the first through hole, the opposite ends thereof being slidable along the slide rails so as to enable either one of the sputtering faces to engage in and close the first through hole.

8. The sputtering apparatus as claimed in claim 7, wherein the chamber is substantially cylindrical and further comprises an upper cover, a bottom cover, and a number of connecting frames, the upper cover and the bottom cover perpendicularly connect two corresponding opposite sides of the first sidewall, each connecting frame perpendicularly protrudes from the first sidewall and surround the entrance of each first through hole.

9. The sputtering apparatus as claimed in claim 8, wherein each first through hole is substantially elongated rectangular, and define a pair of first sides and a pair of second sides, the first sides of the first through holes are parallel to a central axis of the chamber.

10. The sputtering apparatus as claimed in claim 9, wherein one of each pair of slide rails is positioned between the upper cover and one of the second sides, the other of each pair of slide rails is positioned between the bottom cover and the other second side.

11. The sputtering apparatus as claimed in claim 8, wherein the base is substantially rectangular prism and further comprises a second sidewall perpendicularly connecting the sputtering faces and a shaft passing through the base and aligning with a central axis of the base, two opposite ends of the shaft are slidably and rotatably engaged with the slide rails.

12. The sputtering apparatus as claimed in claim 11, wherein each target holder further comprises a flange surrounding the periphery of the second sidewall, the chamber defines a number of threaded holes in each connecting frame, each target holder defines a number of second through holes in the flange spatially corresponding to the threaded holes, each target holder is fastened to the first sidewall by threading a number of bolts into the threaded holes via the second through holes.

13. The sputtering apparatus as claimed in claim 7, wherein each target holder further comprises a pair of sliding blocks correspondingly formed at opposite ends thereof, the target holder is slidably engaged with the slide rails through the sliding blocks.
